(19) United States
(12) Patent Application Publication
(10) Pub. No.: US 2006/0039177 A1
(43) Pub. Date: Feb. 23, 2006

(54) Ferroelectric memory

(76) Inventor: Shinichi Fukada, Tokyo-To (JP)

Correspondence Address: EPSON RESEARCH AND DEVELOPMENT INC;INTELLECTUAL PROPERTY DEPT, 150 RIVER OAKS PARKWAY, SUITE 225, SAN JOSE, CA, 95134, US

(21) Appl. No.: 11/206,412

(22) Filed: Aug. 18, 2005

(30) Foreign Application Priority Data
Aug. 20, 2004 (JP) 2004-240444

(51) Int. Cl. G11C 11/22

(52) U.S. Cl. 365/145

(57) ABSTRACT

A ferroelectric memory has a plurality of adjacent first and second word lines 161 and 162 arranged in word line pairs along a row direction, and a plurality of bit lines 130 arranged along a column direction intersecting the row direction. A plurality of cell capacitors 110 are arranged in a staggered manner within a word line pair and are alternately connected to the first and second word lines 161 and 162 of the word line pair. The first and second word lines 161 and 162 within a word line pair are selected in unison, each cell capacitors is individually selectable by selecting an appropriate bit line and word line pair.

### RELATED APPLICATIONS

Japanese application No. 2004-240444 is hereby incorporated by reference in its entirety.

### BACKGROUND OF THE INVENTION

1. Field of the Invention

The present invention relates to ferroelectric memories (FeRAMs), and more particularly to 1T1C/2T2C stacked type FeRAMs having a structure particularly suited for miniaturization.

2. Description of the Related Art

Conventionally, ferroelectric memories (FeRAMs) have been widely known as nonvolatile memories using polarization hysteresis characteristics of ferroelectric materials. Because FeRAMs are capable of operating with low power consumption and at high speed, demand for FeRAMs is growing. Also, improvement in miniaturization and higher-integration of ferroelectric memories is advancing like in other semiconductor devices such as DRAMs (dynamic random access memories). For example, Japanese Laid-open Patent Application HEI 6-209113 describes a planar type FeRAM. However, a stacked type FeRAM would be preferred over a planar type FeRAM in view of miniaturization and higher-integration. Consequently, stacked type FeRAMs have been rapidly gaining in popularity in recent years.

FIG. 5 is a plan view showing an exemplary structure of a stacked type FeRAM 400 according to a conventional example. In the following discussion, M1, M2, M3, etc. referrers to metal layer 1, metal layer 2, metal layer 3, etc., respectively, each of which is define by a different IC manufacturing process layer. As shown in FIG. 5, the FeRAM 400 includes plate lines (M1) 420 connected to upper plate electrodes 403 of cell capacitors 410, bit lines (M2) 430 connected to lower plate electrodes of cell capacitors 410, word backing lines (M3) 440 coupled to word lines 460, wiring pads (M1) 450 that connect the substrate and the bit lines (M2) 430, and the like. Metal word backing lines 440 help reduce the resistance of word lines 460.

As it would be understood by one versed in the art, each memory cell includes one or more cell capacitors and one or more cell select transistors, all of which are controlled by proper manipulation of their corresponding plate line, word line, and bit line. The operation of a ferroelectric memory cell is well understood in the art and will not be elaborated upon here. A fuller understanding of the operation of a ferroelectric memory may be found in “Emerging Memories, Technologies and Trends” by Betty Prince, Copyright © 2002 by Kluwer Academic Publishers, which is hereby incorporated by reference.

In this FeRAM 400, word lines 460 also serve as gate electrodes of cell selection transistors, i.e. select transistors, and are composed of polysilicon or the like doped with an impurity, such as, for example, phosphorous or the like. To lower the resistance of the word lines 460, the word backing support lines (M3) 440 are provided. It is noted that “M” in the parentheses means metal, “M1” means a wiring layer in a first metal layer counted from the substrate side (in other words, the lowermost metal layer), “M2” means a wiring layer in a second metal layer, and “M3” means a wiring layer in a third metal layer, respectively. It is noted that interlayer dielectric films are provided between metal layers M1 and M2 and between metal layers M2 and M3, respectively.

In FeRAM 400 of the conventional example shown in FIG. 5, word backing lines (M3) 440 are required because the resistance of poly word lines 460, which also serve as the gate electrodes of select transistors, would be too high if word lines 460 were to be used alone as a wiring layer. Also, in addition to the word backing lines 440, the FeRAM 400 requires that bit lines 430 extend orthogonally to word lines 460 and to plate lines 420. In other words, as compared to DRAMs, FeRAM 400 requires one more wiring layer. For this reason, miniaturizing a conventional FeRAMs is complicated due to it requiring least three metal layers.

Another example of a typical FeRAM is disclosed in Advanced 0.5 μm FRAM Device Technology with Full Compatibility of Half-Micron CMOS Logic Device, Tatsuya Yamazaki et al., IEDM Digest of Technical Papers. p. 613 (1997), which is herein incorporated by reference. Additionally, Samsung® has announced a stacked type FeRAM structure in which word lines are arranged on both sides of each plate line. In the Samsung® structure, capacitors are arranged on both sides of each plate line such that the space requirement for wiring layers, as viewed in a plan view, can be reduced. However, with the Samsung® structure, when word lines on both sides of a plate line are simultaneously selected, two capacitors are selected for each bit line. For this reason, word lines on both sides of each plate line need to be used as word lines for different rows, or word lines on both sides of each plate line need to be alternatively selected to read a signal, which imposes a considerable limitation on such process operations as reading and writing.

### OBJECTS OF THE INVENTION

Therefore, the present invention has been made in view of such unsolved problems of the conventional technology described above. It is an object of the present invention to provide a ferroelectric memory that has a structure suitable for miniaturization, and that can execute such operational processes as reading and writing like an ordinary ferroelectric memory.

### SUMMARY OF THE INVENTION

To achieve the object described above, a ferroelectric memory in accord with the present invention is characterized in comprising: a plurality of word lines arranged in a first direction; and a plurality of bit lines arranged a second direction intersecting the first direction, wherein

a word line pair is formed by adjacent first and second word lines,

a plurality of cell capacitors arranged in a staggered manner are alternately connected to the first and second word lines of the word line pair,

the plurality of bit lines are arranged such that the plurality of cell capacitors connected to the word line pair are individually selected by appropriate selection of bit line and a word line pair, and

the pair of the word lines are selected in unison.

It is noted here that the “first direction” may be, for example, a row direction (longitudinal direction), and the “second direction” may be, for example, a column direction (a direction traversing the longitudinal direction). Further, when the “first direction” is defined as a row direction (longitudinal direction), and the “second direction” is defined as a column direction (traversing direction), the first direction and the second direction are orthogonal to each other (in other words, they intersect at 90° with respect to each other), which is one example. However, the “first direction” and the “second direction” in accordance with the present invention are not limited to intersecting at 90° with each other, but include the case where they diagonally intersecting with each other.

Also, the “cell capacitor” is preferably a ferroelectric capacitor having a ferroelectric film and an upper electrode and a lower electrode sandwiching the ferroelectric film in, for example, a vertical direction. As the ferroelectric film, a crystalline film having a perovskite structure, such as, for example, PZT (PbZr_{1-X}Ti_{X}O₃), SBT (SrBi₂Ta₂O₉) or the like is suitable.

Further, the “first direction” of the present invention may be, for example, a longitudinal direction in a plan view, and the “second direction” may be, for example, a traversing direction in a plan view. In the present invention, a plurality of word lines are arranged in a first row, a second row, a third row, . . . , for example, in a longitudinal direction in a plan view, and a plurality of bit lines are arranged in a first column, a second column, a third column, . . . , in a traversing direction in the plan view.

Further, the “word line pair” may be formed, for example, within one process layer (i.e. a first routing layer), and has a structure in which a single routing line is folded in a u-shape (in other words, a folded structure). Also, “arranged in a staggered manner” means arrangement along a zigzag line that may be defined by, for example, Z-letters connected in a longitudinal direction in a plan view. To connect a cell capacitor to a word line means to connect the word line to a gate electrode of a select transistor that selectively controls access to the cell capacitor.

With such a structure, compared to the conventional ferroelectric memory shown in FIG. 5, a space can be created between cell capacitors in the first direction, and therefore the gap between adjacent cell capacitors in the first direction can be reduced.

Also, when selectively controlling a pair of word lines in unison, one cell capacitor is selected for one bit line. For this reason, by the selective control of the word lines, readout and write processing to specific cell capacitors, which do not differ at all from those of an ordinary ferroelectric memory, can be conducted.

Alternatively, the ferroelectric memory may comprise a plurality of word line pairs, wherein the plurality of cell capacitors arranged for one of adjacent sets of the word line pairs and the plurality of cell capacitor arranged for the other of the adjacent sets of the word line pairs are mutually arranged in line symmetry as viewed in a plan view.

With such a structure, cell selection transistors on one side using the word lines in one of the adjacent sets as gate electrodes and cell selection transistors on another side using the word lines in the other of the adjacent sets as gate electrodes can share their sources or drains. Accordingly, the gap between cell capacitors can be further reduced.

Alternatively, the ferroelectric memory may comprise a plurality of common plate lines arranged in the first direction, wherein upper electrodes of the plurality of cell capacitors connected to the word line pairs are connected to one of the common plate lines, and lower electrodes of the plurality of cell capacitors connected to the set of word line pair are connected to the bit line. It is noted here that, in a ferroelectric memory having a stacked structure, an upper electrode of a capacitor is connected to a plate line, and its lower electrode is connected to a bit line.

According to this embodiment, a plate line is shared by the word line pairs, such that a ferroelectric memory having a stacked structure with its plate line layout being simplified can be provided.

Alternatively the ferroelectric memory may comprise a plurality of backing lines that back the plurality of word lines, respectively, wherein the plurality of backing lines and the plurality of plate lines are arranged in a common wiring (i.e. line routing) layer. It is noted that arranging the backing wirings and the common plate lines in a common wiring layer means that the backing wirings and the common plate lines are arranged in the same hierarchical level over the substrate.

According to this embodiment, the backing wirings can be arranged in vacant spaces created between the adjacent ones of the common plate lines, such that the resistance of the word lines can be lowered without increasing the number of wiring layers.

Alternatively, the plurality of bit lines may be arranged in a line routing process layer above the plurality of backing lines and the plurality of common plate lines.

With such a structure, a wider area can be secured for the bit lines.

Alternatively, the ferroelectric memory may comprise a plurality of wiring pads each having an outer size that is greater in the first direction than the second direction, wherein the plurality of wiring pads, the plurality of backing wirings and the plurality of common plate lines are arranged in a common process routing layer, and sources or drains that are shared between cell selection transistors on one side using the word lines in one of the adjacent sets as gate electrodes and cell selection transistors on another side using the word lines in the other of the adjacent sets as gate electrodes are connected to the bit lines through the wiring pads.

With such a structure, the wiring pads can be arranged with an excellent spatial efficiency.

Alternatively, the ferroelectric memory may further comprise a plurality of local routing lines in a process routing layer below the plate lines, wherein the local wirings are arranged between the upper electrodes of the cell capacitors and the common plate lines.

With such a structure, the degree of freedom in designing the common plate lines can be made greater.

Additionally, at least a part of the local routing lines (i.e. wirings) may be composed of a conductive material having a hydrogen diffusion barrier function. It is noted here that the “conductive material having a hydrogen barrier function” is, for example, iridium oxide.

According to this embodiment, diffusion of hydrogen in layers lower than the local wirings can be prevented, and the ferroelectric film cannot be reduced in the process of forming the ferroelectric memory.

Other objects and attainments together with a fuller understanding of the invention will become apparent and appreciated by referring to the following description and claims taken in conjunction with the accompanying drawings.

### BRIEF DESCRIPTION OF THE DRAWINGS

In the drawings wherein like reference symbols refer to like parts.

FIG. 1 is a plan view showing an exemplary structure of an FeRAM in accord with the present invention.

FIG. 2 is a plan view showing an exemplary structure of a word backing line/plate line layer for the FeRAM of FIG. 1.

FIG. 3 is a plan view of the word backing line/plate line layer of an FeRAM incorporating a first local line routing layer in accord with the present invention.

FIG. 4 is a plan view of the word backing line/plate line layer of an FeRAM incorporating a second local line routing layer in accord with the present invention.

FIG. 5 is a plan view of a conventional FeRAM.

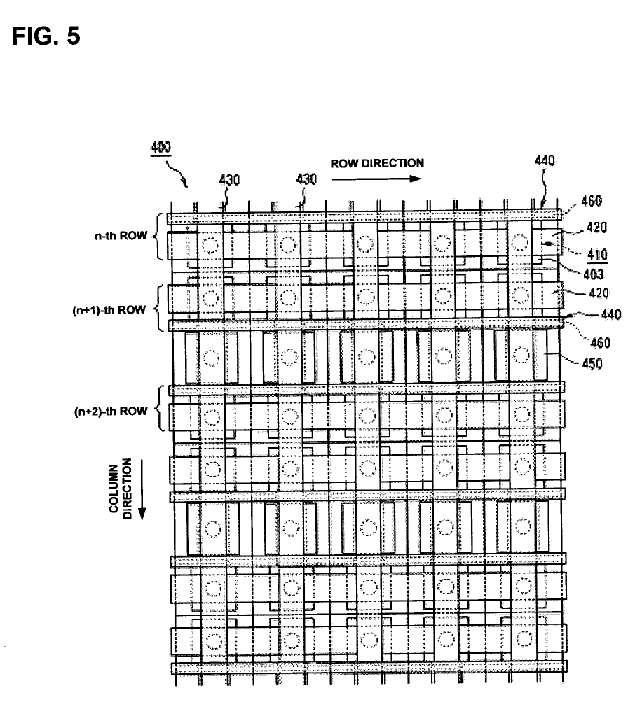

### DESCRIPTION OF THE PREFERRED EMBODIMENTS

A ferroelectric memory in accordance with the present invention is described below with reference to the accompanying drawings. It is noted that plan views include portions that illustrate, for the sake of convenience of explanation, lines which cannot typically be seen due to overlapping wiring layers and dielectric films.

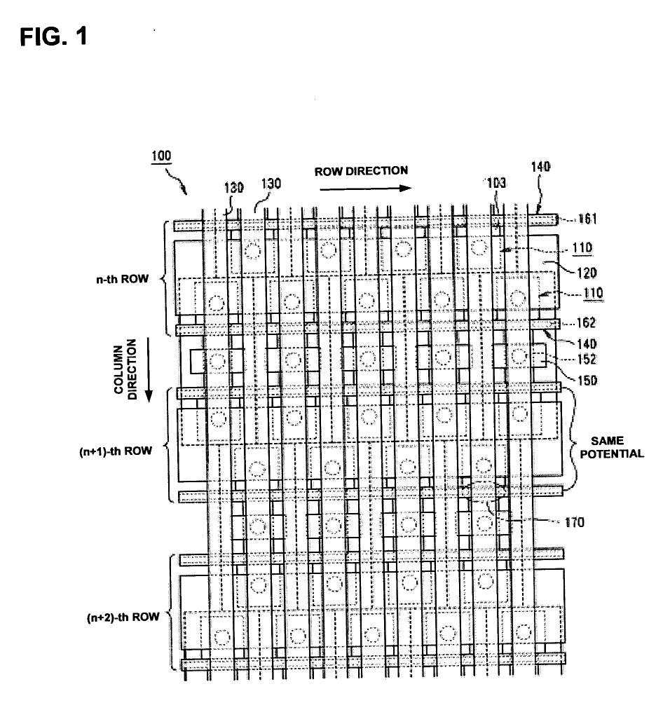

FIG. 1 is a plan view showing an exemplary structure of an FeRAM 100 in accord with the present invention. As shown in FIG. 1, FeRAM 100 is a stacked type ferroelectric memory, and includes a plurality of cell capacitors 110, a plurality of word lines 161 and 162, a plurality of cell selection MOS transistors 170 (hereafter, simply referred to as select transistors) having gate electrodes that are defined by the word lines (i.e. 161 and 162), a plurality of word backing lines 140 (M1), a plurality of plate lines 120 (M1), a plurality of wiring pads 150 (M1), and a plurality of bit lines 130 (M2).

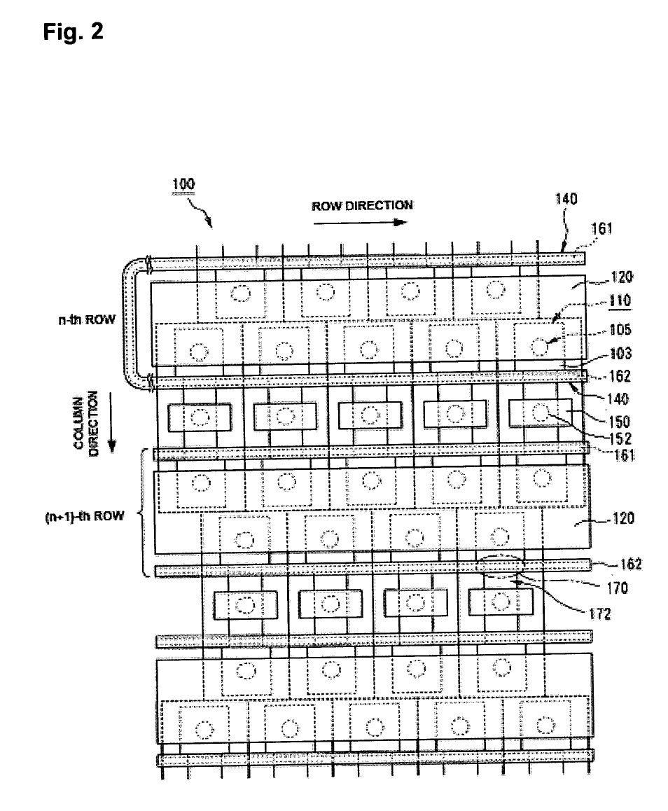

FIG. 2 shows the structure of FIG. 1 with the bit lines removed from the FeRAM 100 clarity of explanation. The plurality of word lines 161 and 162 are alternately arranged along the rows of memory cells. Each pair of adjacent word lines 161 and 162 is coupled together at an end in a u-shape curve (folded structure), as indicated in dash lines. The coupling u-shape coupling curve may be a constructed in a metal layer.

In FeRAM 100, such pairs of word lines (hereafter referred to as “word line pairs”) 161 and 162 are provided in plural sets along the row direction. Using this folded structure, the same voltage can be applied to both word lines (161 and 162) in a word line pair at the same time, and therefore the select transistors 170 along two adjoining rows sharing the word line pair 161 and 162 as their control gate electrodes can be simultaneously turned ON and OFF. As shown, word backing lines 140 are provided on the word lines 161 and 162.

In the present exemplary array architecture, cell capacitors 110 may be typical FeRAM capacitors having an upper electrode plate over a ferroelectric film over a lower electrode plate. For example, a plug electrode 105 (composed of tungsten or the like) is coupled to the source electrode of a select transistor 170, the cell capacitor's lower electrode (not shown) is coupled to plug electrode 105, a ferroelectric film (not shown) is formed on the lower electrode, and the cell capacitor's upper electrode 103 is formed on the ferroelectric film. The ferroelectric film may consist, for example, of PZT type material, SBT type material, or the like.

Plural plate lines 120 are arranged along the row direction, and the upper electrodes 103 of the plural cell capacitors 110 are connected to corresponding plate lines 120 along each row. In the present FeRAM 100, one plate line 120 between a word line pair 161/162 composes a row of the memory elements.

Additionally, in the presently exemplary FeRAM, 100, cell capacitors 110 within a row of memory cells are arranged in each row in a zigzag fashion (i.e. two adjacent rows of capacitors 110 with the capacitors 110 within each adjacent row being offset from each other), and are alternately connected with respect to the respective word lines 161 and 162. In other words, a plurality of first cell capacitors 110 are connected to a first word line 161 within a word line pair, and a plurality of second cell capacitors 110 are connected the second word line 162 within the word line pair. The first and second capacitors 110 are arranged such that their position is shifted from one another by, for example, a half of the pitch in the row direction (or by half the width of a capacitor as defined along the row direction).

Furthermore, a plurality of cell capacitors 110 in an n-th row and a plurality of cell capacitors 110 in a (n+1)-th row are symmetrically aligned with wiring pads 150 between each pair of aligned cell capacitors 110. By such a line symmetrical structure, for example, a first row of select transistors 170 that utilize word line 162 in the n-th row as a control gate electrodes and a second row of select transistors 170 using a word line 161 in the (n+1)-th row as its control gate electrodes can share, for example, drain regions 172. Plug electrodes 152 then connect wiring pads 150 to the lower electrodes of the cell capacitors 110 within the shared drain regions 172.

As shown in FIG. 2, word backing lines 140 (M1), plate lines 120 (M1) and the wiring pads 150 (M1) are formed in the same wiring (i.e. metal routing) layer M1 (in other words, in the same hierarchical level).

Returning to FIG. 1, the plural bit lines 130 (M2) are formed above plate lines 120 (M1) and wiring pads 150 (M1) by means of an interlayer dielectric film (not shown). Each bit line 130 is connected through a wiring pad 150 to the lower electrode of a cell capacitor 110. Although each word line is coupled to a plurality of zig-zag-arranged cell capacitors within each row, each bit lines uniquely selects only one cell capacitor within each row. Thus, by appropriate selection of bit line and word line, each one of the plurality of cell capacitors 110 in the array can be uniquely selected.

In this manner, in the FeRAM 100 in accord with the present invention, two word lines 161 and 162 (of a word line pair) are arranged on both sides of each plate line 120, as viewed in a plan view. However, the cell capacitors 110 are alternately arranged on both sides of the plate line 120, such that, when the word lines 161 and 162 on both sides of the one plate line 120 are simultaneously selected, only one of the cell capacitors 110 is selected by a corresponding one of the bit lines 130. Accordingly, the FeRAM 100 can be operated in a manner that does not differ from the operation of a typical FeRAM.

Also in FeRAM 100, the cell capacitors 110 are alternately arranged on both sides of plate line 120, such that mutually adjacent cell capacitors 110 in a row of cell capacitors are arranged diagonally with respect to one another (in a zig-zag pattern), such that space between adjacent cell capacitors 110 can be preserved. As a result, the pitch in the row direction that is determined by the space between adjacent cell capacitors can be reduced as compared to a conventional FeRAM structure.

Furthermore in the present embodiment, since the cell capacitors 110 are arranged on both sides of each plate line 120, a functionality similar to the structure in which the plate line 120 is folded is realized, and therefore the number of plate lines can be reduced to half of the prior art. Consequently, extra room can be provided for the space requirements of the wiring layer (i.e. metal routing layer) in which the plate lines 120 are formed, and the word backing lines 140 that are disposed in parallel to the plate lines 120 can be arranged in the same wiring layer.

When the cell capacitors 110 are given a square shape or a circular shape, as viewed in a plan, the bit lines can be arranged at half the ordinary pitch such that the bit lines 130 can be given a denser arrangement than that of the wiring layer that includes word backing lines 140, plate lines 120 and the like (hereafter referred to as a “word backing line/plate line layer”). For this reason, considering that an area for the wiring pads 150 should be included in the word backing line/plate line layer, it is more advantageous in terms of space if bit lines 130 are arranged above the word backing line/plate line layer.

In this case, an open space extending in the row direction is created in the word backing line/plate line layer, such that the shape of the wiring pad 150 to be provided in this area can be elongated in the row direction. For the sake of convenience of the photolithography process and the etching process, the wiring pad may preferably be as large as much as possible, and therefore the wiring pad that is elongated in the row direction is effective in increasing the process margin.

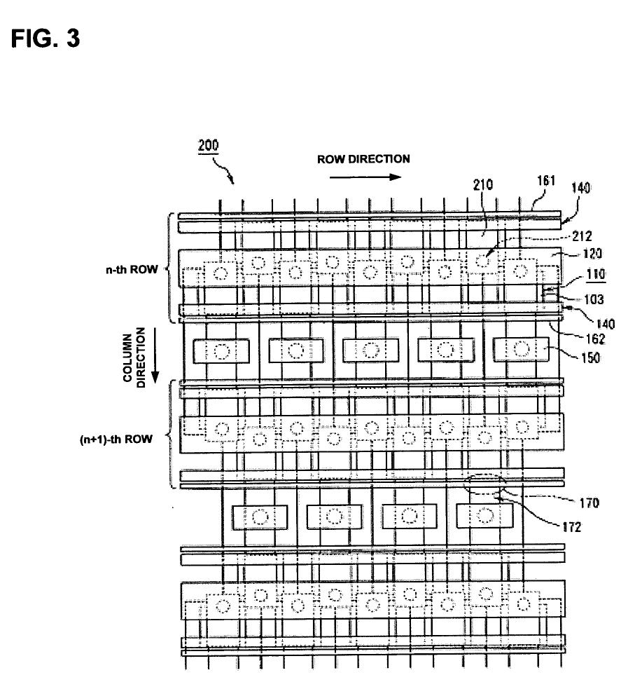

With reference to FIG. 3, a plan view of an exemplary structure of an alternate FeRAM 200 array in accord with an alternate embodiment of the present invention is shown wherein elements similar to those of FeRAM 100 of FIGS. 1 and 2 have similar reference characters and are described above.

In the present FeRAM 200, a local routing layer (i.e. local routing lines) 210 is constructed below word backing line/plate line layer (140/120). Local routing layer 210 is arranged on an upper electrode 103 of each of cell capacitors 110, respectively. Further, plate line 120 is arranged over local routing layer 210. Local routing layer 210 and plate line layer 120 are connected through plug electrodes 212. In other words, plate lines 120 and the upper electrodes 103 are electrically coupled to each other through the local routing layer 210.

With such a structure, the plane configuration of plate lines 120 can be freely designed to some degree; and as a result, as shown in FIG. 3, word backing lines 140 can be arranged without being affected by the positioning of the cell capacitors 110. That is, since word backing lines 140 are now at a different process layer level (i.e. higher process layer) than the upper electrode 103 of each cell capacitor 110, there is no danger of the word backing lines 140 inadvertently making contact with upper electrodes 103, and alignment restrictions on the placing of word backing lines 140 can therefore be relaxed. It should be noted that word backing lines 140 still contact word lines 161/162 to improve the conductivity of the word lines (as is explained in reference to FIG. 2, above). However, in the embodiment of FIG. 3, word backing lines 140 contact word lines 161/162 at predetermined intervals, which are not shown.

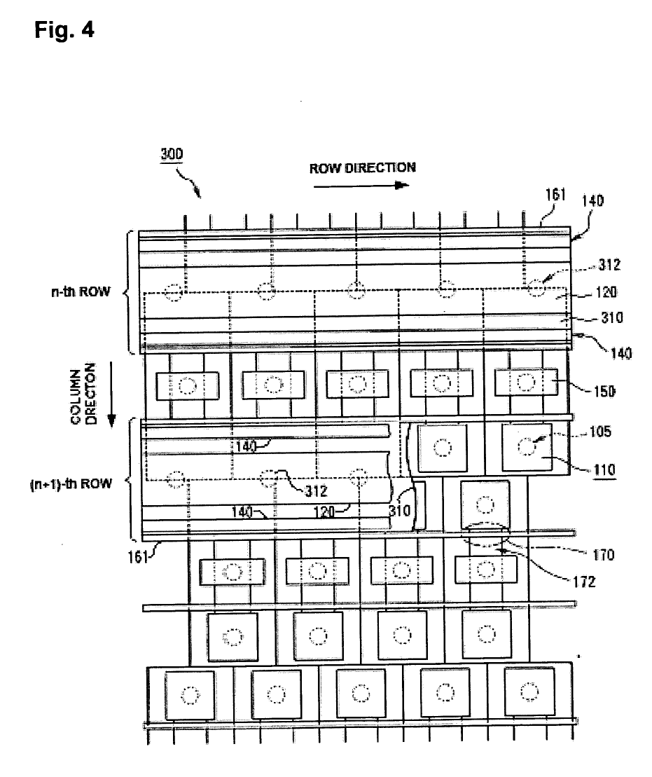

It is further noted that, although not shown in FIG. 3, in the FeRAM 200, bit lines are formed above the word backing wiring/plate line layer through an interlayer dielectric film. Also, the bit lines are provided such that each one of the plural cell capacitors 110 arranged with respect to the word line pair 161 and 162 can be individually selected in each row. In other words, as shown in FIG. 1, each one of the bit lines is connected to the lower electrode of each one of the cell capacitor 110 in each row. Also, each of the bit lines is connected to wiring pads 150 through plug electrodes 152. FIG. 4 is a plan view showing an alternate structure of an FeRAM 300 in accord with the present invention. Elements in FIG. 4 similar to those of the structures of FIGS. 1-3 have similar reference characters, and are described above.

As shown in FIG. 4, FeRAM 300 includes a local routing layer (i.e. local routing lines) 310 below the word backing line/plate line layer (140/120). Local routing layer 310 is different form local routing layer 210 of FIG. 3 in that local routing layer 310 is preferably arranged along each row. Each row of local routing layer 310 covers all cell capacitors 110 within each of the rows.

It is to be noted that local routing layer 310 may be composed of a conductive film having a hydrogen diffusion barrier function, such as, for example, iridium oxide or the like.

Plate line 120 is arranged above local routing layer 310. The local routing layer 310 and plate line 120 are connected through plug electrodes 312.

Further, although not shown in FIG. 4, in this FeRAM 300, a plurality of bit lines are arranged in the column direction above the word backing line/plate line layer through an interlayer dielectric film, like the FeRAMs described above in reference to FIGS. 1-3. With the present structure, diffusion of hydrogen into layers lower than the local routing layer 310 can be prevented, such that the ferroelectric film cannot be reduced during the process of forming the FeRAM 300. The present invention brings about an effect of reducing wiring layers of an FeRAM. However, for an embedded FeRAM, it can be generally said that, because multilayered line routing is required in a logic circuit section, the effect may be small if only the line routing layers in a FeRAM are reduced. However, when the size of a logic section is small and the number of line routing layers required for the logic section is about 2 to 3 layers, then the present invention is effective for simplifying the construction of the IC since the FeRAM in accord with the present invention requires a similar number of line routing layers.

Moreover, when a small capacity FeRAM is embedded in a large-scale logic circuit, the fewer the number of wiring layers to be used in the FeRAM, the more advantageous it would be, considering the fact that the line routing layers of the logic section are used over the FeRAM.

In view of the above, the present invention is considerably effective not only in single purpose FeRAM chips, but also in embedded applications such as FeRAM incorporated into logic circuits, microcomputers (or microprocessors), and the like.

While the invention has been described in conjunction with several specific embodiments, it is evident to those skilled in the art that many further alternatives, modifications and variations will be apparent in light of the foregoing description. Thus, the invention described herein is intended to embrace all such alternatives, modifications, applications and variations as may fall within the spirit and scope of the appended claims.

What is claimed is:

1. A ferroelectric memory comprising:
a plurality of word lines along a first direction, wherein said plurality of word lines are grouped into a plurality of word line pairs, each word line pair consisting of adjacent first and second word lines;
a plurality of bit lines crossing said plurality of word lines, said bit lines being arranged along a second direction traversing said first direction; and
a plurality of cell capacitors between the first and second word lines of said word line pairs;
a plurality of cell select transistors coupled in a one-to-one arrangement to said plurality of cell capacitors for selectively coupling their corresponding cell capacitor to a corresponding bit line, said cell select transistors being responsive to said word lines, and said cell select transistor being alternately coupled to the first and second word lines of said word line pairs;
wherein said first and second word lines in each word line pair are selected in unison; and
wherein each memory cell may be individually selected by appropriate selection of a target word line pair and a target bit line.

2. The ferroelectric memory of claim 1, further comprising an array of rows and columns of memory cells, each memory cell including at least one of said cell capacitors; wherein:
said first direction is defined by rows of said memory cells;
said second direction is defined by columns of said memory cells; and
each word line pair identifies a separate row of memory cells.

3. The ferroelectric memory of claim 1, wherein said plurality of cell capacitors are arranged in a staggered manner between first and second word lines.

4. The ferroelectric memory of claim 3, wherein adjacent staggered cell capacitors between first and second word lines reside within a common process layer and are further arranged to overlap each other.

5. The ferroelectric memory of claim 1, wherein the arrangement of cell capacitors within a first word line pair directly mirrors the arrangement of cell capacitors within an adjacent word line pair.

6. The ferroelectric memory of claim 1, further comprising a plurality of plate lines along said first direction;
wherein each of said cell capacitors includes an upper electrode and a lower electrode, the upper electrode being connected to one of the plate lines, and the lower electrode being selectively coupled to one of the bit lines through a corresponding cell select transistor.

7. The ferroelectric memory of claim 6, further comprising a plurality of backing lines coupled in a one-to-one arrangement to corresponding word lines, said backing lines and said plate lines being constructed within a common process routing layer.

8. The ferroelectric memory of claim 7, wherein the plurality of bit lines reside within a manufacturing process layer above the a process layer within which the backing lines and plate lines reside.

9. The ferroelectric memory of claim 7, further comprising a plurality of wiring pads elongated along said first direction;
wherein:
the plurality of wiring pads, the plurality of backing lines and the plurality of plate lines reside within a common process layer; and
said cell select transistors couple said cell capacitors to their corresponding bit line through the wiring pads.

10. The ferroelectric memory of claim 6, further comprising a plurality of local routing lines defined by a local routing process layer below said plate lines, said local routing lines are arranged to couple the upper electrode of said cell capacitors to their corresponding plate line.

11. The ferroelectric memory of claim 10, wherein at least a part of said local routing lines are composed of a conductive material having a hydrogen diffusion barrier function.

12. The ferroelectric memory cell of claim 1, wherein said first and second word lines within a word line pair are couple to each other at one of their ends.
